(19) United States
(12) Patent Application Publication
(10) Pub. No.: US 2011/0220878 A1
(43) Pub. Date: Sep. 15, 2011

(54) Thin film transistor and method of manufacturing the same

(76) Inventors: Tak-Young Lee, Yongin-City (KR); Byoung-Keon Park, Yongin-City (KR); Yun-Mo Chung, Yongin-City (KR); Jong-Ryuk Park, Yongin-City (KR); Dong-Hyun Lee, Yongin-City (KR); Ki-Yong Lee, Yongin-City (KR); Jin-Wook Seo, Yongin-City (KR); Min-Jae Jeong, Yongin-City (KR); Young-Duck Son, Yongin-City (KR); Byung-Soo So, Yongin-City (KR); Seung-Kyu Park, Yongin-City (KR); Kil-Won Lee, Yongin-City (KR); Jae-Wan Jung, Yongin-City (KR)

(21) Appl. No.: 12/926,210

(22) Filed: Nov. 2, 2010

(30) Foreign Application Priority Data
Mar. 15, 2010 (KR) 10-2010-0022944

(51) Int. Cl. H01L 51/00; H01L 29/772; H01L 21/336

(52) U.S. Cl. 257/40; 257/365; 438/283; 257/E29.242; 257/E51.001; 257/E21.409

(57) ABSTRACT

A thin film transistor (TFT) includes a substrate, and an active region on the substrate including source and drain regions at opposing ends of the active region, a lightly doped region adjacent to at least one of the source region and the drain region, a plurality of channel regions, and a highly doped region between two channel regions of the plurality of channel regions. The TFT includes a gate insulation layer on the active region, and a multiple gate electrode having a plurality of gate electrodes on the gate insulation layer, the plurality of channel regions being disposed below corresponding gate electrodes, and the source region and the drain region being disposed adjacent to outermost portions of the multiple gate electrode. The TFT includes a first interlayer insulation layer on the multiple gate electrode, and source and drain electrodes extending through the first interlayer insulation layer and contacting the respective source and drain regions.

### BACKGROUND

1. Field

The present invention relates to a thin film transistor (TFT), and more particularly, to a TFT capable of reducing a leakage current, and a method of manufacturing the TFT.

2. Description

A thin film transistor (TFT) may include a field effect transistor manufactured using a semiconductor thin film formed on an insulating support substrate. Like other field effect transistors, a TFT may have, e.g., three terminals, a gate, a drain, and a source. The TFT may be used for a switching operation. A switching operation may be performed using the TFT by adjusting a voltage applied to a gate to turn on or off a current flowing between the source and the drain. The TFT may be used in a sensor, a memory device, in an optical device, as a pixel switching unit of flat panel display device, and as a driving unit of a flat panel display device.

### SUMMARY

Embodiments are therefore directed to a thin film transistor and a method of manufacturing a thin film transistor, which substantially overcome one or more of the problems due to the limitations and disadvantages of the related art.

It is therefore a feature of an embodiment to provide a thin film transistor that includes a multiple gate electrode, at least one lightly doped region, and at least one highly doped region.

It is therefore another feature of an embodiment to provide a method of manufacturing a thin film transistor that includes a multiple gate electrode, at least one lightly doped region, and at least one highly doped region.

At least one of the above and other features and advantages may be realized by providing a thin film transistor (TFT) including a substrate. The TFT may include an active region on the substrate including source and drain regions at opposing ends of the active region, a lightly doped region adjacent to at least one of the source region and the drain region, a plurality of channel regions, and a highly doped region between two channel regions of the plurality of channel regions. The TFT may include a gate insulation layer on the active region, a multiple gate electrode including a plurality of gate electrodes on the gate insulation layer, the plurality of channel regions being disposed below corresponding gate electrodes, and the source region and the drain region being disposed adjacent to outermost portions of the multiple gate electrode. The TFT may include a first interlayer insulation layer on the multiple gate electrode, and source and drain electrodes extending through the first interlayer insulation layer and contacting the respective source and drain regions.

The TFT may include a portion of the highly doped region overlapping corresponding gate electrodes of the multiple gate electrode. The TFT may include at least one lightly doped region including a first lightly doped region adjacent to the drain region. The TFT may further include at least one lightly doped region including a second lightly doped region adjacent to the source region.

The source region, the drain region, the highly doped region, and the at least one lightly doped region may be doped with a p-type dopant. The source region, the drain region, the highly doped region, and the at least one lightly doped region may be doped with an n-type dopant.

The multiple gate electrode may have only two gate electrodes. The multiple gate electrode may include three gate electrodes. The active region may include polycrystalline silicon. An organic light emitting device may include the TFT.

At least one of the above and other features and advantages may also be realized by providing a method of manufacturing a thin film transistor (TFT) including forming an active layer on a substrate. The method may include forming a gate insulation layer on the active layer, forming a resist layer on the gate insulation layer, and forming a source region, a drain region, and a highly doped region in the active layer by doping the active layer with a high doping concentration by using the resist layer as a mask. The method may include forming a multiple gate electrode on the substrate after removing the resist layer and after forming the source region, the drain region, and the highly doped region. The method may include forming at least one lightly doped region in an undoped portion of the active layer that is exposed by the multiple gate electrode, forming a first interlayer insulation layer on the multiple gate electrode after forming the at least one lightly doped region, and forming a source electrode and a drain electrode extending through the first interlayer insulation layer and contacting the respective source and drain regions.

The method of manufacturing the TFT may include a portion of the highly doped region being formed to overlap corresponding gate electrodes of the multiple gate electrode. The method may include a width of the resist layer being formed to overlap a portion of the active layer where the at least one lightly doped region is formed to be wider than a width of the gate electrode adjacent to the portion of the active layer where the at least one lightly doped region is formed. The method may include forming a base layer between the substrate and the active layer.

The present invention provides a thin film transistor (TFT) and a method of manufacturing the TFT, wherein a leakage current may be reduced and loss in mobility and an on current may be minimized.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a cross-sectional view of a thin film transistor (TFT) according to an embodiment of the present invention;

FIG. 2 illustrates a cross-sectional view of an active layer of the TFT of FIG. 1;

FIG. 3 illustrates a cross-sectional view of a TFT according to an exemplary embodiment;

FIG. 4 illustrates a circuit diagram illustrating a pixel unit of an organic light emitting device;

FIGS. 5A through 5E illustrate cross-sectional views of a method of manufacturing a TFT, according to an exemplary embodiment;

FIGS. 6A through 6D illustrate cross-sectional views of a method of manufacturing a TFT, according to an exemplary embodiment; and

FIGS. 7A through 7C illustrate graphs showing a relationship between a drain current Id and a gate voltage Vg according to exemplary embodiments and comparative examples.

### DETAILED DESCRIPTION

Korean Patent Application No. 10-2010-0022944, filed on Mar. 15, 2010, in the Korean Intellectual Property Office, and entitled: “Thin Film Transistor and Method of Manufacturing the Same,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

A driving force of a TFT may be improved by, e.g., reducing a leakage current between the source and the drain, increasing mobility of charge carriers, and increasing the on current. To reduce the leakage current of the TFT, e.g., lightly doped regions and/or a multiple gate structure may be selected.

In the TFT including a lightly doped drain (LDD), a leakage current may increase, e.g., producing an increased leakage current tail, while a voltage Vgs increases. In the TFT including the multiple gate structure, a smallest leakage current may be reduced. When both the LDD structure and the multiple gate structure are used in the TFT, both the leakage current tail and the smallest value of the leakage current may be reduced. However, mobility in charge carriers and the on current may also be reduced, which may cause a problem in driving internal circuits.

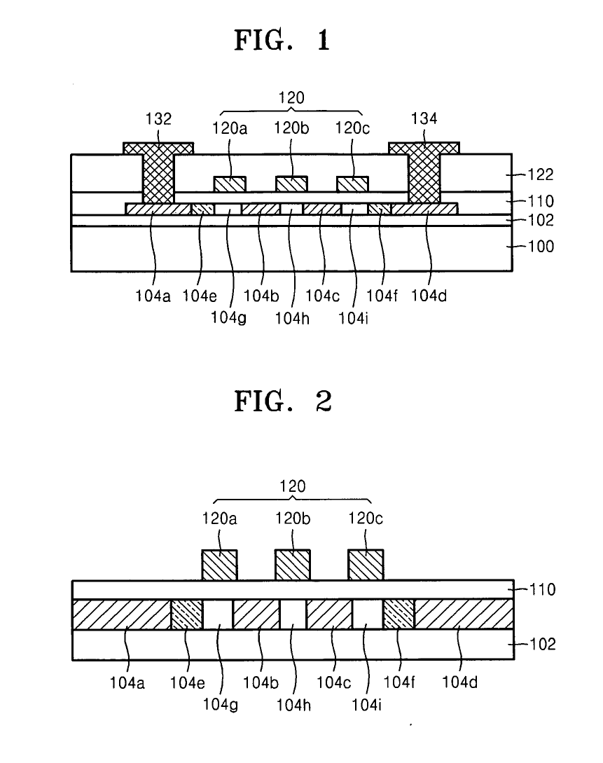

Hereinafter, exemplary embodiments will be described with reference to the attached drawings. FIG. 1 illustrates a cross-sectional view of a thin film transistor (TFT) according to an exemplary embodiment, and FIG. 2 illustrates a cross-sectional view of an active region of the TFT of FIG. 1. Referring to FIGS. 1 and 2, the TFT may be include a base layer 102 formed on a substrate 100.

The substrate 100 may be formed of, e.g., glass, quartz, plastic, silicon, ceramic, a metal, or other suitable materials. The base layer 102 may be used for, e.g., a planarization process step. The base layer 102 may reduce and/or prevent the penetration of impurities into an above lying active region. The base layer 102 may have insulating properties. For example, the base layer 102 may be used for insulation between the substrate 100 and above lying layers, e.g., when a substrate including moving ions or a conductive substrate is used. The base layer 102 may include at least one of, e.g., a silicon oxide (SiO₂), a silicon nitride (SiNₓ), a silicon oxide nitride (SiOₓN_{y}), and like materials. The base layer 102 may include at least one of a SiO₂ layer, a SiNₓ layer, a silicon oxide nitride (SiOₓN_{y}) layer, and various combinations thereof. In an exemplary embodiment, the base layer 102 may be omitted.

Referring to FIGS. 1 and 2, the active region may include, e.g., a source region 104a, a drain region 104d, channel regions 104g, 104h, and 104i, lightly doped regions 104e and 104f, and highly doped regions 104b and 104c. The active layer 104 may be formed directly on the base layer 102 or directly on the substrate 100 in an embodiment where the base layer 102 is omitted. The active region may be a single and continuous layer including a plurality of distinct portions. The active region may be formed in an active layer 104 deposited on the substrate 100. The active layer 104 may be a single and continuous layer. The portions forming the active region may be sequentially arranged in the following order: source region 104a, lightly doped region 104e, channel region 104g, highly doped region 104b, channel region 104h, highly doped region 104c, channel region 104i, lightly doped region 104f, and drain region 104d. The lightly doped regions 104e and 104f may be arranged adjacent to one of the source region 104a or the drain region 104d, e.g., adjacent lateral edges of the lightly doped regions 104e and 104f, and the corresponding source region 104a or drain region 104d may be in direct contact with each other. The highly doped regions 104b and 104c may be spaced apart from each other by a channel region, e.g., channel region 104h. The lightly doped regions 104e and 104f, may be spaced apart from an adjacent highly doped region, e.g., one of highly doped regions 104b and 104c, by a channel region, e.g., one of channel regions 104g and 104i.

The active layer 104 may be formed of a semiconductor material having a crystalline structure, e.g., a monocrystalline semiconductor, a polycrystalline semiconductor, or a semiconductor having micro-crystallinity. According to an exemplary embodiment, the active layer 104 may be formed of a monocrystalline silicon or a polycrystalline silicon.

A gate insulation layer 110 may be formed on, e.g., directly on, the active layer 104. The gate insulation layer 110 may overlap the entire active layer 104. The gate insulation layer 110 may include a single insulating layer or multiple layers. The gate insulation layer may include, e.g., a silicon oxide layer, a silicon nitride layer, a layer including insulating materials, and various combinations thereof.

The multiple gate electrode 120 may be formed on, e.g., directly on, the gate insulation layer 110. In an exemplary embodiment, the multiple gate electrode 120 may include three gate electrodes 120a, 120b, and 120c, that are, e.g., electrically connected to one another. The embodiments are not limited to multiple gate electrodes that include three gate electrodes, and multiple gate electrode 120 may include two gate electrodes or four or more gate electrodes. The gate electrodes 120a, 120b, and 120c, may be formed above respective channel regions 104g, 104h, and 104i of the active region. The multiple gate electrode 120, may reduce a leakage current in an off state of the TFT.

The multiple gate electrode 120 may be include a conductive material. The multiple gate electrode 120 may be include, e.g., Au, Ag, Cu, Ni, Pt, Pd, Al, Mo, W, Ti, various combinations thereof, and various materials in consideration of their adhesive properties to adjacent layers, planarization of layers being stacked, electrical resistance, and processibility. Each gate electrode 120a, 120b, and 120c, may be formed of the same material and/or same combination of materials.

A first interlayer insulation layer 122 may be formed on, e.g., directly on, the multiple gate electrode 120. The first interlayer insulation layer 122 may include a single insulating layer or multiple layers. The first interlayer insulation layer 122 may include, e.g., a silicon oxide layer, a silicon nitride layer, a layer including insulating materials, and various combinations thereof.

A source electrode 132 and a drain electrode 134 may be formed extending through the first interlayer insulation layer 122. The source electrode 132 and drain electrode 134 may also extend through the gate insulation layer 110. The source electrode 132 may contact, e.g., directly contact, the source region 104a of the active region. The drain electrode 134 may contact, e.g., directly contact, the drain region 104d of the active region. The source electrode 132 and the drain electrode 134 may include a conductive material. The source electrode 132 and the drain electrode 134 may include, e.g., Au, Ag, Cu, Ni, Pt, Pd, Al, Mo, W, Ti, and various combinations thereof. The source electrode 132 and the drain electrode 134 may be formed of the same material or difference materials. The source electrode 132 and the drain electrode 134 may be formed of the same material and/or same combinations of materials as the multiple gate electrode 120.

The source region 104a and the drain region 104d may be formed at respective edges, e.g., lateral ends, of the active region. Therefore, the source electrode 132 and drain electrode 134 may be formed above respective edges, e.g., lateral ends, of the active region. The source region 104a and the drain region 104d may be arranged surrounding outermost portions of the multiple gate electrode 120, e.g., gate electrodes 120a and 120c. The channel regions 104g, 104h, and 104i, may be formed below the multiple gate electrodes 120a, 120b, and 120c, respectively.

In an exemplary embodiment, the lightly doped region 104e of the active layer 104 may be formed between the source region 104a and the channel region 104g. The source electrode 132 may be adjacent to the lightly doped region 104e. The source electrode 132 may not overlap the lightly doped region 104e portion of the active region, e.g., the source electrode 132 may substantially overlap only the source region 104a. The lightly doped region 104f may be formed between the drain region 104d and the channel region 104i. At least the lightly doped region 104f may be a lightly doped drain region (LDD). The drain electrode 134 may be adjacent to the lightly doped region 104f. The drain electrode 134 may not overlap the lightly doped region 104f portion of the active region, e.g., the drain electrode 134 may substantially overlap only the drain region 104d. The highly doped regions 104b and 104c may be formed between corresponding channel regions, e.g., channel regions 104g, 104h, and 104i. A portion of the highly doped regions 104b and 104c may overlap the multiple gate electrode 120. For example, as shown in FIG. 1, highly doped region 104b may overlap portions of gate electrodes 120a and 120b, and highly doped region 104c may overlap portions of gate electrodes 120b and 120c.

Without intending to be bound by this theory, the lightly doped regions 104e and 104f may reduce and/or prevent a phenomenon whereby a leakage current increases while a gate-source voltage Vgs increases or while the voltage Vgs decreases in an NMOS transistor. The highly doped regions 104b and 104c may reduce a channel length and/or minimize loss of the on current in the TFT. By using the combination of the multiple gate structure, the lightly doped region structure, and forming the highly doped region between the channel regions, the loss of the on current may be minimized and/or the leakage current may be effectively reduced. The highly doped regions 104b and 104c may be formed to overlap portions of individual gate electrodes of the multiple gate electrode 120, so that a portion with low resistance may be extended to further increase an on current.

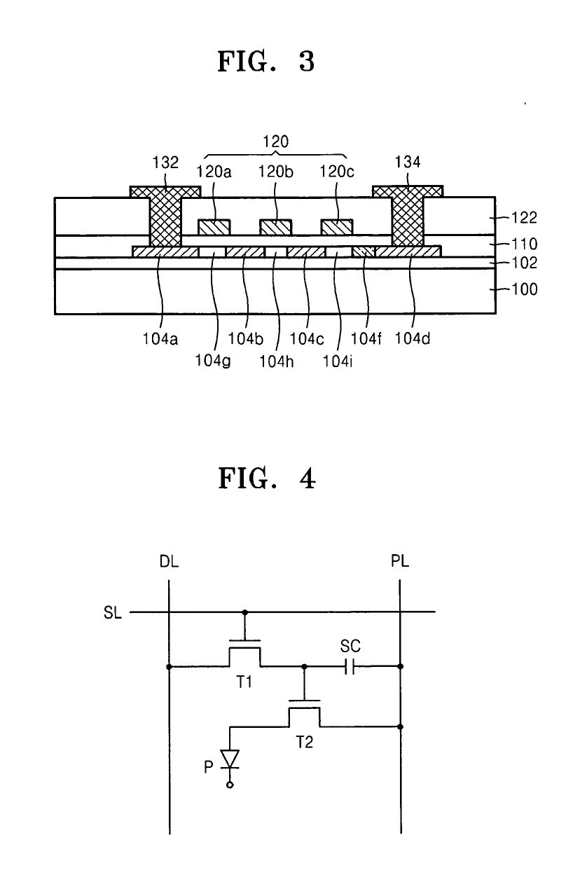

FIG. 3 illustrates a cross-sectional view of a TFT according to an exemplary embodiment. The TFT of FIG. 3 may be similar to the TFT of FIG. 1.

Referring to FIG. 3, the TFT may include a lightly doped region 104f, e.g., a LDD structure, formed adjacent to the drain region 104d. The TFT may not include a lightly doped region formed adjacent to the source region 104a. In various types of transistors, e.g., an n-type metal oxide semiconductor (NMOS) TFT, electrons moving from the source region 104a to the drain region 104d may be accelerated. Slowing down the acceleration of the electrons using, e.g., the lightly doped region 104f, may reduce and/or prevent damage to the gate insulation layer 110 due to hot carriers and/or reduce a leakage current.

Without intending to be bound by this theory, in the lightly doped region structure, a lightly doped region, e.g., lightly doped region 104f, may be formed at a drain to mitigate an electric field and/or to suppress charge carriers being accelerated near the drain. In an off state of the TFT, a source may not have an effect on the leakage current if the charge carriers are not being accelerated at that time. In an off state and in a circuit in which a source region and a drain region are not fixed, positions of the source region and the drain region may be exchanged according to a voltage of two nodes of the source region and the drain region. Thus, a lightly doped region structure may be formed adjacent to both the source region 104a and the drain region 104d. When the source region 104a and the drain region 104d are fixed, a lightly doped region structure, e.g., the LDD structure, may be formed only at the drain region.

The TFT of FIGS. 1 and 3 may be one of various types of transistors, e.g., a p-type MOS (PMOS) TFT, an NMOS TFT, or the like. In an exemplary embodiment of a PMOS TFT, the source region 104a, the drain region 104d, and the highly doped regions 104b and 104c, may be p+ doped regions, and the lightly doped regions 104e and 104f may be p-doped regions. In an exemplary embodiment of an NMOS TFT, the source region 104a, the drain region 104d, and the highly doped regions 104b and 104c may be n+ doped regions, and the light doped regions 104e and 104f may be n−doped regions.

FIG. 4 illustrates a circuit diagram of a pixel unit of a display device, e.g., an organic light emitting diode display device, that may include the TFTs of at least one of FIGS. 1 and 3.

Referring to FIG. 4, the pixel unit may include a selection line SL that selects a pixel to be driven, a data line DL that applies a voltage to a pixel, e.g., an organic light emitting diode pixel. The pixel unit may include a power source line PL that supplies power, and a storage capacitor SC that accumulates charges according to a voltage difference between the data line DL and the power source line PL. The pixel unit may include a switching unit T1 that controls data flow in the data line DL according to a signal of the selection line SL. The pixel unit may include a driving unit T2 that allows a current to flow according to a voltage due to the charges accumulated in the storage capacitor SC. A light emitting device P, e.g., an organic light emitting diode, may be driven by a current that flows based on a function of the driving unit T2.

Embodiments of the TFTs, e.g., according to the exemplary embodiments illustrates in FIGS. 1 and 3, may be applied to the switching unit T1 and/or the driving unit T2 of the circuit diagram for a display device illustrated in FIG. 4. Embodiments of the TFTs may be used as, e.g., a switching unit and/or a driving unit, of light emitting devices other than the organic light emitting device, such as plasma display devices and liquid crystal devices.

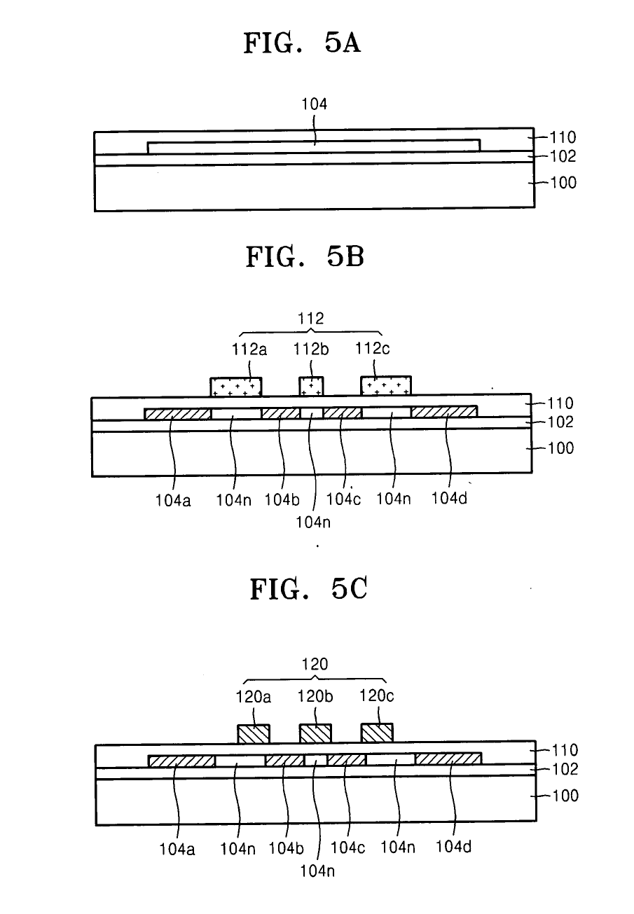

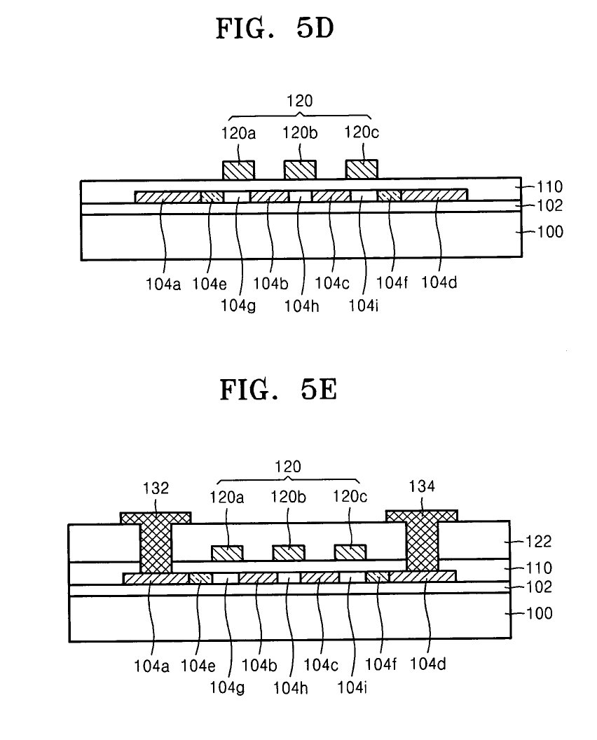

FIGS. 5A through 5E illustrate cross-sectional views of an exemplary method of manufacturing a TFT, e.g., the TFT of FIG. 1.

Referring to FIG. 5A, the base layer 102 may be formed, e.g., deposited, on the substrate 100. The substrate 100 may be formed of glass, quartz, plastic, silicon, ceramic, a metal, or other suitable materials. The base layer 102 may include at least one of a silicon oxide (SiO₂), a silicon nitride (SiNₓ), or a silicon oxide nitride (SiOₓN_{y}). The base layer 102 may be used, e.g., for planarization and/or to prevent penetration of impurities into the active region. The base layer 102 may be used for insulation, e.g., when a substrate including moving ions or a conductive substrate is used.

The active layer 104 may be formed on the base layer 102, e.g., by forming a p-type semiconductor layer on the base layer 102 and patterning the same. The active layer 104 may be formed of a semiconductor material having a crystalline structure, e.g., a monocrystalline semiconductor, a polycrystalline semiconductor, or a semiconductor having micro-crystallinity. According to an exemplary embodiment, the active layer 104 may be formed of a monocrystalline silicon or a polycrystalline silicon.

The gate insulation layer 110 may formed on the active layer 104. The gate insulation layer 110 may cover, e.g., overlap substantially an entire length, of the active layer 104. The gate insulation layer 110 may include a single insulating layer or multiple layers. The gate insulation layer 110 may include, e.g., a silicon oxide layer, a silicon nitride layer, a layer including insulating materials, and various combinations thereof.

Referring to FIG. 5B, a resist layer pattern 112 including a plurality of resist layers, e.g., resist layers 112a, 112b, and 112c, may be formed on the gate insulation layer 110. The resist layers 112a, 112b, and 112c may overlap an undoped region 104n of the active layer 104. The resist layers, e.g., 112a, 112b, and 112c, of the resist layer pattern 112, may be spaced apart from adjacent resist layers. The number of resist layers may correspond to the number of gate electrodes of the subsequently formed multiple gate electrode 120.

The resist layers 112a, 112b, and 112c, may define channel regions of the active region formed in a later process step, e.g., the resist layers 112a, 112b, and 112c, may overlap an area of the active layer 104 where the channel regions will be formed. The resist layers 112a and 112c may define lightly doped regions of the active region formed in a later process step, e.g., the resist layers 112a and 112c may overlap an area of the active layer 104 where at least one lightly doped region will be formed. The resist layers 112a, 112b, and 112c may define the highly doped regions of the active region formed in later process step, e.g., the highly doped regions 104b and 104c may be formed in the exposed area between the resist layers 112a, 112b, and 112c. The resist layers 112a and 112c may define the source and drain regions, respectively, e.g., the source region 104a may be later formed in an area adjacent to the resist layer 112a, and the drain region 104d may be later formed in an area adjacent to the resist layer 112c.

According to an exemplary embodiment, the resist layer pattern 112 may be used as a mask to perform doping, e.g., p+ doping of a p− type doping process, of the active layer 104. Embodiments are not limited to p− type doping, e.g., n-type doping may be performed. According to an exemplary embodiment, when p-type doping is performed, the p+ doping may be used to form p+ doped regions. The p+ doped regions of the active layer 104 may include, e.g., a p+ doped source region 104a, a p+ doped highly doped region 104b, a p+ doped highly doped region 104c, and a p+ doped drain region 104d. The p+ doped regions 104b and 104c may correspond to highly doped regions formed between respective channel regions of the active layer 104. A storage capacitor bottom electrode (not shown) may be formed on the substrate 100 at the same time by the p+ doping process. In an exemplary embodiment, Boron may be added as a dopant for p+ doping, e.g., boron may be added by ion-implanting diboraine (B₂H₆).

The resist layer pattern 112 may include resist layers 112a and 112c that are wider than the corresponding gate electrodes 120a and 120c that will be formed in a later step. In an exemplary embodiment, the undoped region 104n of the active layer 104 that is covered by the resist layer pattern 112 during p+ doping may be exposed, e.g., not covered by the multiple gate electrode 120, after the multiple gate electrode 120 is formed. The resist layers 112a, 112b, and 112c may be formed such that the highly doped regions 104b and 104c that are doped by p+ doping overlap portions of at least one of the gate electrodes 120a, 120b and 120c. For example, the highly doped region 104b may overlap portions, e.g., adjacent edges, of the gate electrodes 120a and 120b, and the highly doped region 104c may overlap portions, e.g., adjacent edges, of the gate electrodes 120b and 120c.

Referring to FIG. 5C, after the resist layer pattern 112 is removed, a conductive layer may be formed on the substrate 100. The conductive layer may be patterned to form the multiple gate electrode 120. According to an exemplary embodiment, the multiple gate electrode 120 may include a plurality of multiple gate electrodes, e.g., gate electrodes 120a, 120b, and 120c. The conductive layer may include, e.g., Au, Ag, Cu, Ni, Pt, Pd, Al, Mo, W, Ti, an alloy thereof, and is not limited thereto and may include various materials in consideration of their adhesive properties to adjacent layers, planarization of layers being stacked, electrical resistance, and processibility. The multiple gate electrode 120 may be aligned such that the highly doped regions 104b and 104c are disposed between at least two adjacent gate electrodes of the gate electrodes 120a, 120b, and 120c.

Referring to FIG. 5D, the multiple gate electrode 120 may be used as a mask to perform p− doping of the p-type doping in the active layer 104, e.g., a portion of the undoped regions 104n. The p− doping of the undoped region 104n may use a self-alignment method to form lightly doped regions 104e and 104f. Boron may be used as a dopant for the p− doping, e.g., boron may be added by ion-implanting diboraine (B₂H₆). The lightly doped regions 104e and 104f may be doped at a lower concentration than the highly doped regions 104b and 104c.

After performing p− doping, the channel regions 104g, 104h, and 104i, may be formed below the multiple gate electrodes 120a, 120b, and 120c, respectively. The source region 104a and the drain region 104d may be arranged in the active region adjacent to outer portions, e.g., outermost portions, of the gate electrodes 120a and 120c, respectively. The gate electrodes 120a and 120c may not overlap the source region 104a and the drain region 104d, respectively. The lightly doped region 104e may be formed between the source region 104a and the channel region 104g, and the lightly doped region 104f may be formed between the drain region 104d and the channel region 104i. The highly doped regions 104b and 104c may be arranged between the at least two channel regions of the channel regions 104g, 104h, and 104i. A portion of the highly doped regions 104b and 104c may overlap with the at least two gate electrodes of the gate electrodes 120a, 120b, and 120c.

Referring to FIG. 5E, the first interlayer insulation layer 122 may be formed on the multiple gate electrode 120, e.g., on the gate electrodes 120a, 120b, and 120c. The source electrode 132 and the drain electrode 134 may be formed extending through the first interlayer insulation layer 122 and the gate insulation layer 110. The source electrode 132 and the drain electrode 134 may contact, e.g., directly contact, the source region 104a and the drain region 104d, respectively. The first interlayer insulation layer 122 may include at least one of an inorganic insulation layer, e.g., a silicon oxide layer and a silicon nitride layer, and an organic insulation layer. The source electrode 132 and the drain electrode 134 may include a conductive material, e.g., Au, Ag, Cu, Ni, Pt, Pd, Al, Mo, W, Ti, and an alloy thereof.

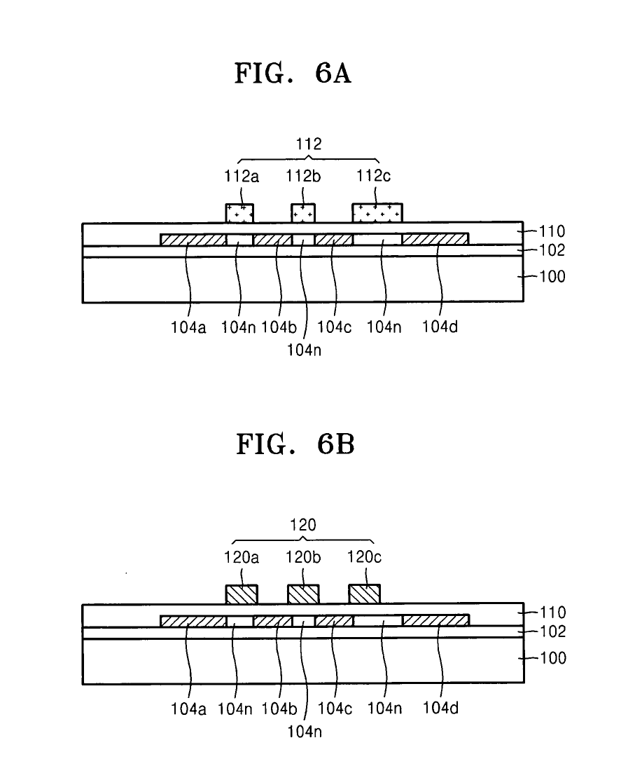

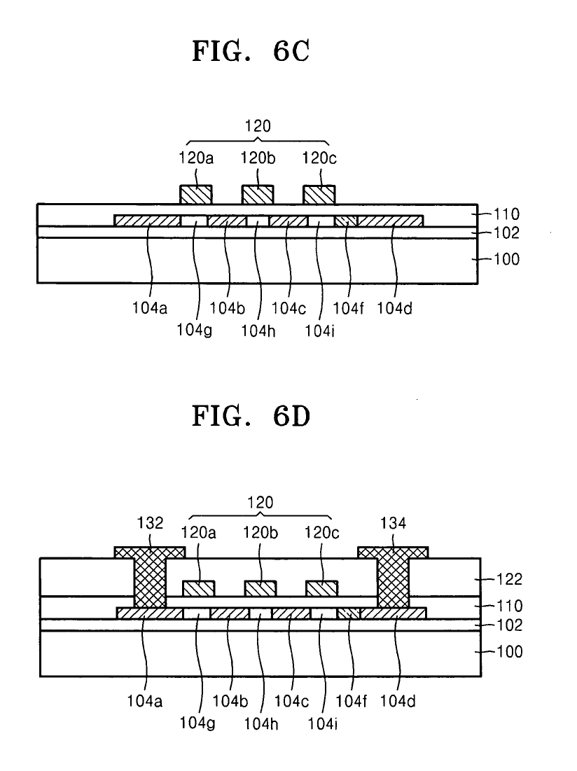

FIGS. 6A through 6D illustrate cross-sectional views of a method of manufacturing a TFT, e.g., the TFT of FIG. 3, according to an exemplary embodiment.

The method illustrated in FIGS. 6A through 6D include the lightly doped region formed adjacent to one of the source region 104a or the drain region 104d. In an exemplary embodiment, the lightly doped region structure may be an LDD structure, e.g., the lightly doped region may be a lightly doped drain region formed adjacent to the drain region 104d. Descriptions related to the same elements as illustrated in FIGS. 5A through 5E may not be repeated herein.

Referring to FIG. 6A, the base layer 102 may be formed on a substrate 100. An active layer 104, e.g., a p-type semiconductor layer, may be formed on the base layer 102. The gate insulation layer 110 may be formed on the active layer 104. The resist layer pattern 112 may be formed on the gate insulation layer 110, the resist layer pattern 112 may include a plurality of resist layers, e.g., resist layers 112a, 112b, and 112c, formed on the gate insulation layer 110. The resist layers 112a and 112b may be formed to define channel regions and highly doped regions between the channel regions of the active region. The resist layer 112c adjacent to the drain region may be relatively wider than the resist layers 112a and 112b. According to an exemplary embodiment, the wider resist layer 112c may overlap an area where a channel region, e.g., channel region 104i, and a lightly doped drain region, e.g., lightly doped region 104f, may be formed in later process steps.

By using the resist layer 112 as a mask doping, e.g., p− type doping, may be performed to form doped regions in the active layer 104. According to an exemplary embodiment, p-type doping is performed to form p+ doped regions of the active layer 104 that may include, e.g., the p+ doped source region 104a, the p+ doped drain region 104b, the p+ doped highly doped region 104c, and the p+ doped highly doped region 104d. During the p+ doping process, a storage capacitor bottom electrode (not shown) may be simultaneously formed on the substrate 100.

Referring to FIG. 6B, the resist layer pattern 112 may be removed, and the conductive layer may be formed on the substrate 100. The conductive layer may be patterned to form the multiple gate electrode 120. The multiple gate electrode 120 may include a plurality of gate electrodes, e.g., gate electrodes 120a, 120b, and 120c. The multiple gate electrode 120 may aligned such that the highly doped regions 104b and 104c are disposed between at least two adjacent gate electrodes of the gate electrodes 120a, 120b, and 120c. A portion of the active layer 104, e.g., undoped region 104n, that is not p+-doped may be exposed by one of the gate electrodes, e.g., the gate electrode 120c.

Referring to FIG. 6C, the multiple gate electrode 120 may be used as a mask to perform p− type doping, e.g., p− doping, in the active layer 104. The p− doping may use a self-alignment method to form the lightly doped region 104f.

After performing the p− doping, the channel regions 104g, 104h, and 104i, may be formed below the multiple gate electrodes 120a, 120b, and 120c, respectively. The source region 104a and the drain region 104d may be arranged adjacent to outer portions, e.g., outermost portions, of the multiple gate electrodes 120a and 120c, respectively. The lightly doped region 104f may be formed between the drain region 104d and the channel region 104i. According to an exemplary embodiment, the lightly doped region 104e adjacent to the source region 104a may be excluded, e.g., in the instance where the source and drain regions of the TFT are fixed. The highly doped regions 104b and 104c may be formed between at least two adjacent channel regions of the channel regions 104g, 104h, and 104i. A portion of the highly doped regions 104b and 104c may overlap with a portion of at least one adjacent gate electrodes of the gate electrodes 120a, 120b, and 120c.

Referring to FIG. 6D, the first interlayer insulation layer 122 may be formed on multiple gate electrode 120, e.g., cover the gate electrodes 120a, 120b, and 120c. The source electrode 132 and the drain electrode 134 may be formed extending through the first interlayer insulation layer 122. The source electrodes 132 and the drain electrode 134 may extend through the gate insulation layer 110, and may contact, e.g., directly contact, the source region 104a and the drain region 104b, respectively.

In the above exemplary embodiments, the source region 104a and the drain region 104b are designated, but positions thereof may be exchanged according to a voltage applied thereto. The multiple gate electrode 120 described above may be formed of three gate electrodes, two gate electrodes, or four or more gate electrodes. In addition, although a PMOS TFT is described above, an NMOS TFT may also be used.

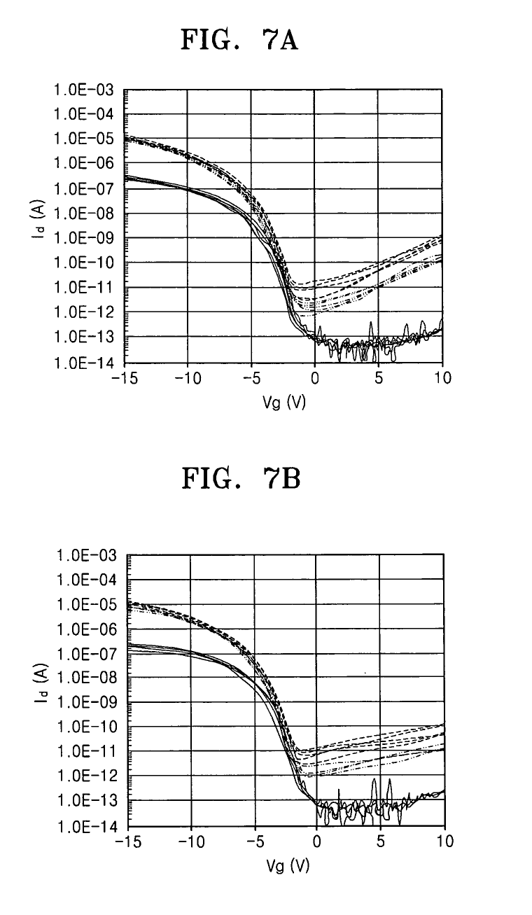

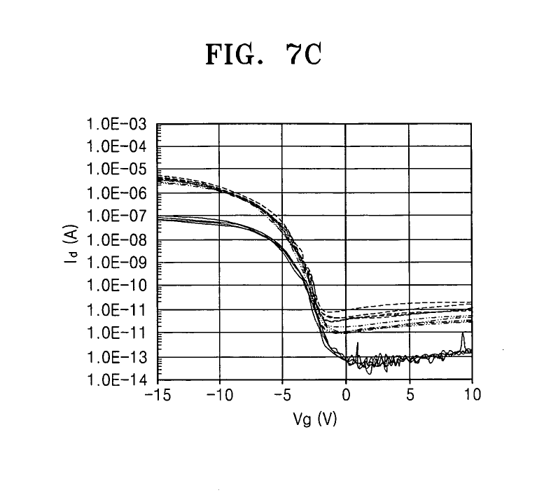

FIGS. 7A through 7C illustrate characteristics of TFTs according to exemplary embodiments and to comparative examples. FIGS. 7A through 7C illustrate graphs showing a relationship between a drain current Id and a gate voltage Vg according to exemplary embodiments and to comparative examples. Referring to FIGS. 7A through 7C, drain-source voltages Vds are −0.1V, −5.1V, and −10.1V and an off current increases as the voltages Vds increase.

FIG. 7A is an Id-Vg graph of a TFT according to a comparative example including a multiple gate electrode and a highly doped region structure, and not including lightly doped regions. Referring to FIG. 7A, an on current of the TFT according to the comparative example is 10⁻⁵ A, and a smallest value of an off current thereof is in a range of 10⁻¹¹ A to 10⁻¹³ A. The higher the voltage Vg, the higher the off current increases.

FIG. 7B is an Id-Vg graph of a TFT according to an exemplary embodiment including a multiple gate electrode, a highly doped region structure, and a lightly doped region structure. In the TFT of the exemplary embodiment, the highly doped region overlaps at least one gate electrode of the multiple gate electrodes. Referring to FIG. 7B, an on current of the TFT is 10⁻⁵ A, and a smallest value of an off current thereof is in a range of 10⁻¹¹ A to 10⁻¹³ A. The results are is similar to the on current and the smallest value of the off current of the comparative example, but the degree of increase of the off current as the gate voltage Vg increases is smaller than the comparative example.

FIG. 7C is an Id-Vg graph of a TFT according to an exemplary embodiment including a multiple gate electrode, a highly doped region structure, and a lightly doped region structure. In the TFT of FIG. 7B, the highly doped region does not overlap a gate electrode of the multiple gate electrode. Referring to FIG. 7C, an on current of the TFT is smaller than 10⁻⁵ A, and a smallest value of an off current thereof is in a range of 10⁻¹¹ A to 10⁻¹³ A. The results are similar to the smallest value of the off current of the comparative example, but the degree of increase of the off current as the gate voltage Vg increases is smaller than the comparative example and the embodiment of FIG. 7B.

Without intending to be bound by this theory, according to the embodiments, using the multiple gate electrode structure, the lightly doped region structure, and the highly doped region structure including highly doped regions between adjacent gate electrodes of the multiple gate electrode, a smallest leakage current may be reduced, a phenomenon that a leakage current increases as a gate voltage increases may be reduced or prevented, and reduction in an on current is prevented. Accordingly, a TFT having reliability and an improved driving force may be provided.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A thin film transistor (TFT), comprising:
a substrate;
an active region on the substrate including source and drain regions at opposing ends of the active region, a lightly doped region adjacent to at least one of the source region and the drain region, a plurality of channel regions, and a highly doped region between two channel regions of the plurality of channel regions;
a gate insulation layer on the active region;
a multiple gate electrode including a plurality of gate electrodes on the gate insulation layer, the plurality of channel regions being disposed below corresponding gate electrodes, and the source region and the drain region being disposed adjacent to outermost portions of the multiple gate electrode;
a first interlayer insulation layer on the multiple gate electrode; and
source and drain electrodes extending through the first interlayer insulation layer and contacting the respective source and drain regions.

2. The TFT as claimed in claim 1, wherein a portion of the highly doped region overlaps corresponding gate electrodes of the multiple gate electrode.

3. The TFT as claimed in claim 1, wherein the at least one lightly doped region includes a first lightly doped region adjacent to the drain region.

4. The TFT as claimed in claim 3, wherein the at least one lightly doped region includes a second lightly doped region adjacent to the source region.

5. The TFT as claimed in claim 1, wherein the source region, the drain region, the highly doped region, and the at least one lightly doped region are doped with a p-type dopant.

6. The TFT as claimed in claim 1, wherein the source region, the drain region, the highly doped region, and the at least one lightly doped region are doped with an n-type dopant.

7. The TFT as claimed in claim 1, wherein the multiple gate electrode has only two gate electrodes.

8. The TFT as claimed in claim 1, wherein the multiple gate electrode includes three gate electrodes.

9. The TFT as claimed in claim 1, wherein the active region includes polycrystalline silicon.

10. An organic light emitting device comprising the TFT of claim 1.

11. A method of manufacturing a thin film transistor (TFT), the method comprising:
forming an active layer on a substrate;
forming a gate insulation layer on the active layer;
forming a resist layer on the gate insulation layer;
forming a source region, a drain region, and a highly doped region in the active layer by doping the active layer with a high doping concentration by using the resist layer as a mask;
forming a multiple gate electrode on the substrate after removing the resist layer and after forming the source region, the drain region, and the highly doped region;
forming at least one lightly doped region in an undoped portion of the active layer that is exposed by the multiple gate electrode;
forming a first interlayer insulation layer on the multiple gate electrode after forming the at least one lightly doped region; and
forming a source electrode and a drain electrode extending through the first interlayer insulation layer and contacting the respective source and drain regions.

12. The method as claimed in claim 11, wherein a portion of the highly doped region is formed to overlap corresponding gate electrodes of the multiple gate electrode.

13. The method as claimed in claim 11, wherein the active layer includes polycrystalline silicon.

14. The method as claimed in claim 11, wherein forming the at least one lightly doped region includes forming a first lightly doped region adjacent to the drain region.

15. The method as claimed in claim 14, wherein forming the at least one lightly doped region includes forming a second lightly doped region adjacent to the source region.

16. The method as claimed in claim 14, wherein a width of the resist layer overlapping a portion of the active layer where the at least one lightly doped region is formed is wider than a width of the gate electrode adjacent to the portion of the active layer where the at least one lightly doped region is formed.

17. The method as claimed in claim 11, wherein the doping with the high doping concentration or the low doping concentration is performed using a p-type dopant.

18. The method as claimed in claim 11, wherein the doping with the high doping concentration or the low doping concentration is performed using an n-type dopant.

19. The method as claimed in claim 11, wherein the multiple gate electrode includes three gate electrodes.

20. The method as claimed in claim 11, further comprising forming a base layer between the substrate and the active layer.
